(19) United States
(12) Patent Application Publication
(10) Pub. No.: US 2025/0072192 A1
(43) Pub. Date: Feb. 27, 2025

(54) SEMICONDUCTOR DEVICE

(71) Applicant: EPISTAR CORPORATION, Hsinchu (TW)

(72) Inventors: Jih-Kang CHEN, Hsinchu (TW); Hsien-Pen WU, Hsinchu (TW); Shih-Wei YANG, Hsinchu (TW)

(21) Appl. No.: 18/810,092

(22) Filed: Aug. 20, 2024

(30) Foreign Application Priority Data
Aug. 22, 2023 (TW) 112131451

(51) Int. Cl. H01L 33/62; H01L 25/075; H01L 33/10; H01L 33/22

(52) U.S. Cl. CPC H01L 33/62; H01L 25/0753; H01L 33/10; H01L 33/22

(57) ABSTRACT

A semiconductor device is provided, which includes a semiconductor epitaxial structure, a first insulating layer, a metal layer, a second insulating layer, a first electrode pad, a second electrode pad, and an intermediate structure. The semiconductor epitaxial structure includes an active region and has a first sidewall and a first upper surface. The first insulating layer covers the first sidewall and the first upper surface of the semiconductor epitaxial structure and has a second upper surface. The metal layer is located on the first insulating layer. The second insulating layer is located on the metal layer. The first electrode pad and the second electrode pad are located on the second insulating layer. The intermediate structure is located between the first insulating layer and the metal layer. The second upper surface of the first insulating layer has a portion directly contacts the metal layer.

### CROSS REFERENCE TO RELATED APPLICATIONS

This application claims the right of priority based on TW application Serial No. 112131451, filed on Aug. 22, 2023, which is incorporated by reference herein in its entirety.

### FIELD OF DISCLOSURE

The present disclosure relates to a semiconductor device, and in particular to a semiconductor optoelectronic device.

### BACKGROUND OF THE DISCLOSURE

Semiconductor devices are widely applied in various fields, such as illumination, display, communication or power supply system, and research and development on related materials and products continues. For example, Group III-V semiconductor materials including Group III and Group V elements may be applied in various semiconductor optoelectronic devices, such as light-emitting diodes, laser diodes, photodetectors or solar cells, or may be used in power devices, such as switching devices or rectifiers. As one kind of the semiconductor light-emitting devices, the light-emitting diodes may have advantages of low power consumption, fast response speed, small size, and long operating lifetime, thus the light-emitting diodes are widely used in various fields. The light-emitting diode may include a p-type compound semiconductor, an n-type compound semiconductor composed of III-V group elements, and an active region between them. Under an action of an external electric field, holes and electrons may recombine in the active region and emit light.

### SUMMARY OF THE DISCLOSURE

The present disclosure provides a semiconductor device. The semiconductor device includes a semiconductor epitaxial structure, a first insulating layer, a metal layer, a second insulating layer, a first electrode pad, a second electrode pad, and an intermediate structure. The semiconductor epitaxial structure includes an active region and has a first sidewall and a first upper surface. The first insulating layer covers the first sidewall and the first upper surface of the semiconductor epitaxial structure and has a second upper surface. The metal layer is located on the first insulating layer. The second insulating layer is located on the metal layer. The first electrode pad and the second electrode pad are located on the second insulating layer. The intermediate structure is located between the first insulating layer and the metal layer. The second upper surface of the first insulating layer has a portion directly contacts the metal layer.

### BRIEF DESCRIPTION OF THE DRAWINGS

FIG. 1 shows a schematic top view of a semiconductor device in accordance with an embodiment of the present disclosure.

FIG. 2 shows a schematic sectional view of the semiconductor device of FIG. 1 along A-A′ line.

FIG. 3 shows a schematic sectional view of the semiconductor device of FIG. 1 along B-B′ line.

FIG. 4 shows a schematic sectional view of the semiconductor device of FIG. 1 along C-C′ line.

FIG. 5 shows a schematic sectional view of a semiconductor device along C-C′ line in accordance with another embodiment of the present disclosure.

FIG. 6 shows a schematic sectional view of a semiconductor component in accordance with an embodiment of the present disclosure.

FIG. 7 shows a schematic top view of a semiconductor component in accordance with an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

In the present disclosure, if not otherwise specified, the general formula InGaP represents Inₓ₀Ga₁₋ₓ₀P, wherein 0<x0<1; the general formula AlInP represents Alₓ₁In₁₋ₓ₁P, wherein 0<x1<1; the general formula InGaN represents Inx₂Ga₁₋ₓ₂N, wherein 0<x2<1; the general formula AlGaN represents Alₓ₃Ga₁₋ₓ₃N, wherein 0<x3<1; the general formula AlGaInP represents Alₓ₄Gaₓ₅In₁₋ₓ₄₋ₓ₅P, wherein 0<x4<1, and 0<x5<1; the general formula InGaAsP represents Inₓ₆Ga₁₋ₓ₆Asₓ₇P₁₋ₓ₇, wherein 0<x6<1, and 0<x7<1; the general formula AlGaInAs represents Alₓ₈Gaₓ₉In₁₋ₓ₈₋ₓ₉As, wherein 0<x8<1, and 0<x9<1; the general formula InGaNAs represents Inₓ₁₀Ga₁₋ₓ₁₀Nₓ₁₁As₁₋ₓ₁₁, wherein 0<x10<1, and 0<x11<1; the general formula InGaAs represents Inₓ₁₂Ga₁₋ₓ₁₂As, wherein 0<x12<1; the general formula AlGaAs represents Alₓ₁₃Ga₁₋ₓ₁₃As, wherein 0<x13<1; and the general formula AlInGaN represents Al₁₄Inₓ₁₅In₁₋ₓ₁₄₋ₓ₁₅N, wherein 0<x14<1, and 0<x15<1. The content of each element may be adjusted for different purposes, for example, for adjusting the energy gap, or when the semiconductor device is a light-emitting device, the peak wavelength or dominant wavelength may be adjusted. However, the present disclosure is not limited thereto.

The semiconductor device of the present disclosure is, for example, a light-emitting device (such as a light-emitting diode or a laser diode), a light absorbing device (such as a photo-detector) or a non-illumination device. The qualitative or quantitative analysis of the composition and/or dopant contained in each layer of the semiconductor device of the present disclosure may be conducted by any suitable method, for example, a secondary ion mass spectrometer (SIMS). A thickness of each layer may be obtained by any suitable method, such as a transmission electron microscopy (TEM) or a scanning electron microscope (SEM).

Those with ordinary knowledge in the art should understand that other member(s) may be added on the basis of each embodiment described below. For example, if not otherwise specified, a description similar to “a first layer/structure is on or under a second layer/structure” may include an embodiment in which the first layer/structure is in direct contact with (or physically/directly contacts) the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

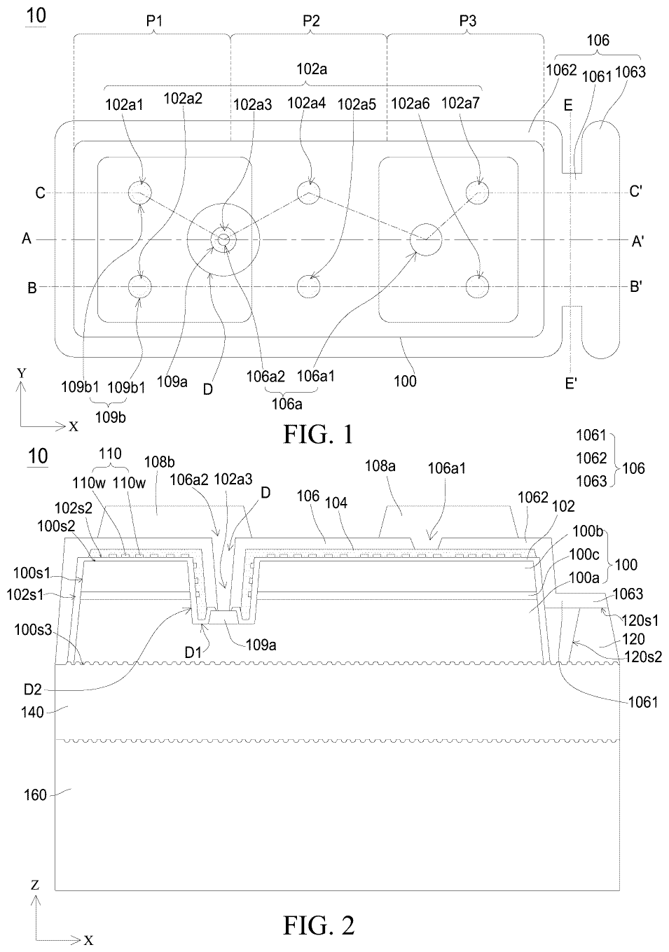

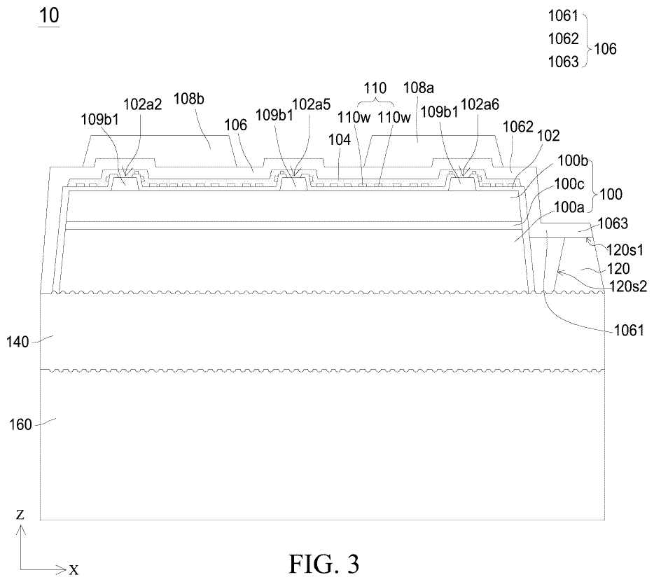

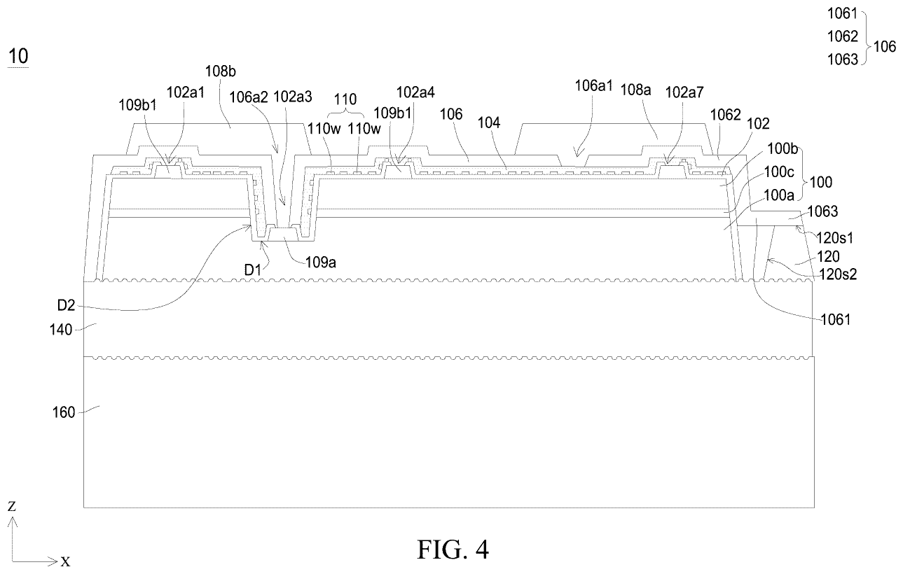

FIG. 1 shows a schematic top view of a semiconductor device 10 in accordance with an embodiment of the present disclosure. FIG. 2 shows a schematic sectional view of the semiconductor device 10 of FIG. 1 along A-A′ line. FIG. 3 shows a schematic sectional view of the semiconductor device 10 of FIG. 1 along B-B′ line. FIG. 4 shows a schematic sectional view of the semiconductor device 10 of FIG. 1 along C-C′ line.

As shown in FIG. 1 to FIG. 4, the semiconductor device 10 includes a semiconductor epitaxial structure 100. The semiconductor epitaxial structure 100 may include a first semiconductor structure 100a, a second semiconductor structure 100b, and an active region 100c. The semiconductor epitaxial structure 100 may be formed by methods, such as metal-organic chemical vapor deposition (MOCVD), molecular beam epitaxy (MBE) or hydride vapor deposition (HVPE). The first semiconductor structure 100a and the second semiconductor structure 100b in the semiconductor epitaxial structure 100 have different conductivity types. In this embodiment, the semiconductor device 10 is the semiconductor optoelectronic device, such as a light-emitting device, and the first semiconductor structure 100a and the second semiconductor structure 100b may respectively provide electrons and holes, or holes and electrons to the active region 100c, and the electrons and the holes may be combined in the active region 100c to emit light with a specific wavelength. In accordance with an embodiment, a top-view area of the semiconductor device 10 may be less than 10,000 μm², such as in a range of 100 μm² to 5,000 μm². For example, the top-view area may be in a range of 500 μm² to 1,000 μm², 500 μm² to 2,000 μm², or 500 μm² to 3,500 μm².

Each layer in the first semiconductor structure 100a may have a first conductivity type, and each layer in the second semiconductor structure 100b may have a second conductivity type different from the first conductivity type. In an embodiment, the first conductivity type is n-type and the second conductivity type is p-type; in another embodiment, the first conductivity type is p-type and the second conductivity type is n-type. The conductivity type of each layer may be adjusted by a dopant. In an embodiment, the dopant may include an element from Group II, Group IV or Group VI of the periodic table of elements, such as C, Zn, Si, Ge, Sn, Se, Mg or Te. Each layer in the first semiconductor structure 100a and the second semiconductor structure 100b may respectively include a Group III-V semiconductor material. The Group III-V semiconductor material may include an element or elements containing aluminum (Al), gallium (Ga), arsenic (As), phosphorus (P), nitrogen (N) or indium (In). In accordance with an embodiment, the Group III-V semiconductor material may be a binary Group III-V semiconductor material (such as GaAs, GaP or GaN), a ternary Group III-V semiconductor material (such as InGaAs, AlGaAs, InGaP, AlInP, InGaN or AlGaN) or a quaternary Group III-V semiconductor material (such as AlGaInAs, AlGaInP, AlInGaN, InGaAsP, InGaNAs or AlGaAsP).

The semiconductor epitaxial structure 100 may include a double heterostructure (DH), a double-side double heterostructure (DDH) or a multiple quantum wells (MQW) structure. In accordance with an embodiment, when operating the semiconductor device 10, the active region 100c may emit a light, such as visible light or invisible light. The light emitted by the semiconductor device 10 is determined by the material composition of the active region 100c. For example, when the material of the active region 100c includes AlGaN, it may emit ultraviolet light with a peak wavelength of 250 nm to 400 nm; when the material of the active region 100c includes InGaN, it may emit deep blue light or blue light with a peak wavelength of 400 nm to 490 nm, green light with a peak wavelength of 490 nm to 550 nm, or yellow or red light with a peak wavelength of 560 nm to 650 nm; when the material of the active region 100c includes InGaP or AlGaInP, it may emit yellow light, orange light or red light with a peak wavelength of 530 nm to 700 nm; when the material of the active region 100c includes InGaAs, InGaAsP, AlGaAs or AlGaInAs, it may emit infrared light with a peak wavelength of 700 nm to 1700 nm.

As shown in FIG. 2, the semiconductor epitaxial structure 100 has a first sidewall 100s1 and a first upper surface 100s2, and further has a first lower surface 100s3. The first sidewall 100s1 is between the first upper surface 100s2 and the first lower surface 100s3 and connects the first upper surface 100s2 and the first lower surface 100s3. In this embodiment, the semiconductor epitaxial structure 100 has a recess D. The recess D extends from the first upper surface 100s2 toward the first lower surface 100s3. A portion of the first semiconductor structure 100a is located at the bottom of the recess D. As shown in FIG. 2, the semiconductor epitaxial structure 100 has a second upper surface D1 and a second sidewall D2. The recess D may be defined by the second upper surface D1 and the second sidewall D2. A top-view shape of the recess D may be a circular, an elliptical, a rectangular or another polygonal shape. The first sidewall 100s1 may be an outer sidewall of the semiconductor epitaxial structure 100, and the second sidewall D2 may be an inner sidewall of the semiconductor epitaxial structure 100.

The semiconductor device 10 further includes a first insulating layer 102, a metal layer 104, and a second insulating layer 106. The first insulating layer 102 covers the first sidewall 100s1 and the first upper surface 100s2 of the semiconductor epitaxial structure 100. The first insulating layer 102 has a third sidewall 102s1 and a third upper surface 102s2. The metal layer 104 is located on the first insulating layer 102. The second insulating layer 106 is located on the metal layer 104. A portion of the third upper surface 102s2 of the first insulating layer 102 is in direct contact with the metal layer 104.

As shown in FIG. 1, the first insulating layer 102 has a plurality of the first openings 102a, and the second insulating layer 106 has a plurality of the second openings 106a. In this embodiment, the number of the first openings 102a is greater than the number of the second openings 106a. Therefore, when operating the semiconductor device 10, current spreads more easily and it may help to achieve uniform current distribution. The plurality of the first openings 102a may have two or more different widths. In accordance with an embodiment, when the semiconductor epitaxial structure 100 is equally divided into N parts with the same length in a length direction (such as an X direction), one to ten of the plurality of first openings 102a may be distributed in each part, and N may be 2, 3, 4 or 5. In accordance with an embodiment, when there is a need for further miniaturization of the semiconductor device 10 (for example, the top-view area of the semiconductor device 10 is less than 5000 μm²), three or less than three first openings 102a may be distributed in each part. As shown in FIG. 1, in this embodiment, the semiconductor epitaxial structure 100 is equal divided into three parts (such as a first region P1, a second region P2 and a third region P3) with the same length in a length direction (such as the X direction), there may be 2 or 3 the first openings 102a distributed in each part. In this embodiment, through the arrangement of the plurality of the first openings 102a and the plurality of the second openings 106a, when operating the semiconductor device 10, the current may be spread more uniformly in the semiconductor epitaxial structure 100.

In order to make the description clear, in the embodiment as shown in FIG. 1 to FIG. 4, the number of the first openings 102a is seven (i.e., first openings 102a1˜102a7), and the number of the second openings 106a is two (i.e., second openings 106a1 and 106a2). As shown in FIG. 1, in this embodiment, the first opening 102a1, the first opening 102a2 and the first opening 102a3 are distributed in the first region P1; the first opening 102a4 and the first opening 102a5 are distributed in the second region P2; the first opening 102a6 and the first opening 102a7 are distributed in the third region P3. The width of the first opening 102a3 may be greater than the width of any one of the other first openings (i.e., the first openings 102a1, 102a2, and 102a4˜102a7). When viewed from above, the first openings 102a other than the first opening 102a3 may be arranged into a two-dimensional matrix, as shown in FIG. 1, the first openings 102a other than the first opening 102a3 in the embodiment forms a two-dimensional matrix of 3×2.

In this embodiment, the second opening 106a2 is distributed in the first region P1, and the second opening 106a1 is distributed in the third region P3. The widths of the second opening 106a1 and the second opening 106a2 may be the same or different. In this embodiment, the second opening 106a1 is not overlapped with any one of the plurality of the first openings 102a in the length direction (such as the X direction) and the width direction (such as the Y direction). This design may help to make the current diffusing into different positions in the semiconductor epitaxial structure 100 so as to increase uniformity. In this embodiment, as shown in FIG. 2, the second opening 106a2 and the first opening 102a3 overlap in the vertical direction (such as the Z direction) to form a current path connected to the first semiconductor structure 100a. A width of each of the second openings 106a1, 106a2 may be greater than a width of each of the first openings 102a1 to 102a7. In accordance with an embodiment, the width of each of the first openings 102a1 to 102a7 may be in a range of 0.5 μm to 6 μm, and the width of each of the second openings 106a1 to 106a2 may be in the range of 4.5 μm to 10 μm.

The first insulating layer 102 and the second insulating layer 106 may be formed by chemical vapor deposition (CVD), such as plasma enhanced chemical vapor deposition (PECVD) or atomic layer deposition (ALD). The materials of the first insulating layer 102 and the second insulating layer 106 may be the same or different. For example, the materials of the first insulating layer 102 and the second insulating layer 106 may include oxides or nitrides, such as titanium oxide (TiO₂), silicon oxide (SiO₂), aluminum nitride (AlN), aluminum oxide (Al₂O₃), or thallium oxide (Ta₂O₅). In accordance with an embodiment, the thickness of the first insulating layer 102 may be in a range of 200 Å to 5000 Å. The thickness of the second insulating layer 106 may be in a range of 200 Å to 5000 Å.

The metal layer 104 may be formed by physical vapor deposition (PVD), such as evaporation or sputtering. The material of the metal layer 104 may include gold (Au), silver (Ag) or aluminum (Al). In an embodiment, the first insulating layer 102 may have a distributed Bragg reflector (DBR) structure to further enhance the function of reflecting light. The distributed Bragg reflector may be formed by alternately stacking a plurality of first sub-layers (not shown) and a plurality of second sub-layers (not shown). The first sub-layer and the second sub-layer have different refractive indexes. In accordance with an embodiment, the combination of the first sub-layer/second sub-layer is, for example, SiO₂/Al₂O₃, SiO₂/TiO₂, or SiO₂/Nb₂O₅.

The semiconductor device 10 further includes a first electrode pad 108a and a second electrode pad 108b. As shown in FIG. 1 to FIG. 4, the first electrode pad 108a and the second electrode pad 108b are located on the second insulating layer 106. The first electrode pad 108a and the second electrode pad 108b may be respectively a single-layer structure or a multi-layer structure. The materials of the first electrode pad 108a and the second electrode pad 108b may be the same or different. In accordance with an embodiment, the materials of the first electrode pad 108a and the second electrode pad 108b include metal oxides, metals, or alloys. The metal oxides include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metals include nickel (Ni), titanium (Ti), platinum (Pt), palladium (Pd), silver (Ag), gold (Au), aluminum (Al), tin (Sn), copper (Cu), germanium (Ge), beryllium (Be) or zinc (Zn). The alloy may include two or more of the above metals, such as germanium gold nickel (GeAuNi), beryllium gold (BeAu), germanium gold (GeAu) or zinc gold (ZnAu).

As shown in FIG. 2, the semiconductor device 10 may optionally include a first contact structure 109a, which is located in the recess D and is in direct contact with the first semiconductor structure 100a in the semiconductor epitaxial structure 100. As shown in FIG. 1 and FIG. 3, the semiconductor device 10 may optionally include a second contact structure 109b located on the semiconductor epitaxial structure 100 and include a plurality of portions 109b1 separated from each other. The plurality of portions 109b1 are in direct contact with the second semiconductor structure 100b in the semiconductor epitaxial structure 100. The materials of the first contact structure 109a and the second contact structure 109b may be metal or alloy. The metal may include germanium (Ge), beryllium (Be), zinc (Zn), gold (Au), nickel (Ni), or copper (Cu). The alloy may include two or more of the above metals, such as germanium gold nickel (GeAuNi), beryllium gold (BeAu), germanium gold (GeAu), or zinc gold (ZnAu).

In this embodiment, as shown in FIG. 1 to FIG. 4, the first electrode pad 108a fills in the second opening 106a1 and directly contacts the metal layer 104 to form an electrical connection. The second electrode pad 108b fills in the second opening 106a2 and the first opening 102a3 and directly contacts the first contact structure 109a to form an electrical connection. The metal layer 104 fills in the first opening 102a1, the first opening 102a2, the first opening 102a4, the first opening 102a5, the first opening 102a6 and the first opening 102a7, and directly contacts with the plurality of portions 109b1 that separated from each other in the second contact structure 109b to form an electrical connection. As mentioned above, in other words, the first electrode pad 108a is electrically connected to the second semiconductor structure 100b through the metal layer 104 and the second contact structure 109b. The second electrode pad 108b is electrically connected to the first semiconductor structure 100a through the first contact structure 109a.

In this embodiment, a portion of the metal layer 104 is located in the recess D of the semiconductor epitaxial structure 100. As shown in FIG. 2 to FIG. 4, a portion of the metal layer 104 covers the second sidewall D2. The metal layer 104 may be devoid of contacting the first contact structure 109a. Specifically, the portion of the metal layer 104 located in the recess D may be isolated from the first contact structure 109a and the second electrode pad 108b by the first insulating layer 102 and/or the second insulating layer 106 to avoid directly contacting with the second electrode pad 108b or the first contact structure 109a that may cause a short circuit. In an embodiment, by distributing the metal layer 104 in the recess D, a reflective area may be further increased, which helps to improve the luminous efficiency of the semiconductor device.

The semiconductor device 10 further includes an intermediate structure 110. The intermediate structure 110 is located between the first insulating layer 102 and the metal layer 104. As shown in FIG. 2 to FIG. 4, the intermediate structure 110 directly contacts the first insulating layer 102 and the metal layer 104. Specifically, in this embodiment, the intermediate structure 110 is mainly used as an adhesive material to strengthen the adhesion between the first insulating layer 102 and the metal layer 104, and to improve the yield of the devices by avoiding a peeling issue which results from poor adhesion between the first insulating layer 102 and the metal layer 104. In accordance with an embodiment, the intermediate structure 110 may include a transparent conductive compound. The transparent conductive compound may be a metal oxide, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). According to this embodiment, the intermediate structure 110 may be discontinuously distributed between the first insulating layer 102 and the metal layer 104. For example, as shown in FIG. 2, the intermediate structure 110 may have a plurality of island-like structures 110w interspersed between the first insulating layer 102 and the metal layer 104. The plurality of island-like structures 110w may be located on the third upper surface 102s2, and the metal layer 104 fills in spaces between the plurality of island-like structures 110w and directly contacts the third upper surface 102s2. In another embodiment, the intermediate structure 110 may be continuously distributed between the first insulating layer 102 and the metal layer 104. For example, the intermediate structure 110 may be formed as an uninterrupted film covering the third upper surface 102s2, and the metal layer 104 may not directly contact the first insulating layer 102, or may directly contact the third upper surface 102s2 at or near edges of the first insulating layer 102. In accordance with an embodiment, a thickness of the intermediate structure 110 may be in a range of greater than 0 Å and less than 100 Å, thereby the adhesion of the first insulating layer 102 and the metal layer 104 may be further improved. Specifically, the intermediate structure 110 may be formed by physical vapor deposition (PVD), such as evaporation or sputtering.

The semiconductor device 10 may optionally include a support structure 120. The support structure 120 is separated from the semiconductor epitaxial structure 100 by a distance. The support structure 120 may include the same material as the semiconductor epitaxial structure 100. For example, the support structure 120 may have the same Group III-V semiconductor material layers as the first semiconductor structure 100a. In accordance with an embodiment, an epitaxial structure including the support structure 120 and the semiconductor epitaxial structure 100 may be formed by epitaxial growth, and then by removing a portion of the epitaxial structure, the support structure 120 and the semiconductor epitaxial structure 100 may be formed and separated. As shown in FIG. 2 to FIG. 4, a height of the support structure 120 may be lower than a height of the semiconductor epitaxial structure 100. The second insulating layer 106 may extend from above the semiconductor epitaxial structure 100 to cover the support structure 120. As shown in FIG. 1 to FIG. 4, a portion of the second insulating layer 106 covers and directly contacts the support structure 120. The support structure 120 has a fourth upper surface 120s1 and a fourth sidewall 120s2. The second insulating layer 106 may cover and directly contact the fourth upper surface 120s1 and/or the fourth sidewall 120s2.

The semiconductor device 10 may optionally include a connecting layer 140, and optionally include a base 160. As shown in FIG. 2 to FIG. 4, the connecting layer 140 and the base 160 are located under the semiconductor epitaxial structure 100. The connecting layer 140 is located between the semiconductor epitaxial structure 100 and the base 160 to join the semiconductor epitaxial structure 100 and the base 160. The base 160 may include a conductive material or an insulating material, the conductive material may include gallium arsenide (GaAs), indium phosphide (InP), silicon carbide (SiC), gallium phosphide (GaP), zinc oxide (ZnO), nitride Gallium (GaN), aluminum nitride (AlN), germanium (Ge) or silicon (Si); the insulating material may include sapphire, glass, diamond, aluminum nitride (AlN), quartz, acrylic, or epoxy. In this embodiment, the base 160 is a bonding substrate, which may be used to support the semiconductor epitaxial structure 100 and other structures. The connecting layer 140 may be electrically insulating. The material of the connecting layer 140 may include a polymer material, such as benzocyclobutene (BCB), epoxy, polyimide, silicone, aluminum oxide (Al₂O₃), or silicon oxide (SiO₂).

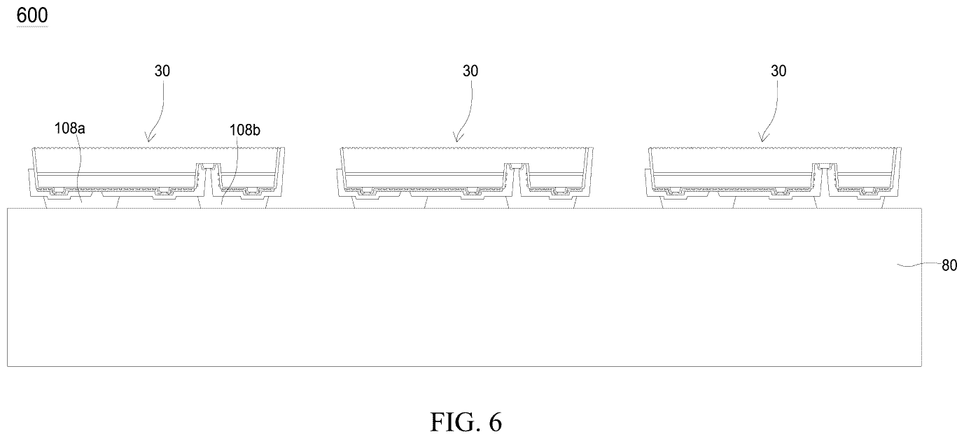

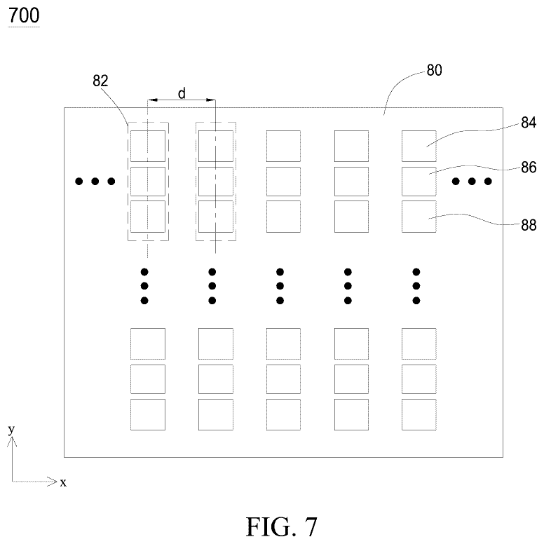

Specifically, the second insulating layer 106, the support structure 120, the connecting layer 140 and the base 160 may play a role in temporarily fixing the semiconductor device 10. For example, the second insulating layer 106 has a first portion 1061 located between the support structure 120 and the semiconductor epitaxial structure 100, and the first portion 1061 may form a weakened structure, and when it is needed to transfer the semiconductor device 10 to another carrier board (such as the carrier board 80 shown in FIG. 6 or FIG. 7), the semiconductor epitaxial structure 100 can be separated from the support structure 120, the connecting layer 140 and the base 160 by removing the connecting layer 140 and applying an external force to break the first portion 1061 of the second insulating layer 106, thereby a semiconductor device without the base 160, the support structure 120 and the connecting layer 140 can be formed.

Methods for removing the connecting layer 140 may include etching, laser lift-off, or heating. As shown in FIG. 1 and FIG. 2, the second insulating layer 106 may further include a second portion 1062 on the semiconductor epitaxial structure 100 and a third portion 1063 on the support structure 120. The width of the first portion 1061 may be designed to be smaller than the width of the second portion 1062, and also smaller than the width of the third portion 1063. In this way, the weakened structure may be formed at the position of the first portion 1061. When the semiconductor device is subjected to an external force, the stress may concentrate easily on the weakened structure, making the second insulating layer 106 easy to be broken at the position where the E-E′ line passes in FIG. 1. In this embodiment, the support structure 120 is disposed on one side of the semiconductor epitaxial structure 100. In another embodiment, the support structure 120 may have the plurality of parts separated from each other (not shown), and these parts may be arranged symmetrically with respect to the semiconductor epitaxial structure 100 when viewed from above. This arrangement can avoid the semiconductor device 10 from being tilted easily during transfer when the stress is too concentrated on one side of the semiconductor epitaxial structure 100, so the transfer yield of the semiconductor device 10 may be elevated.

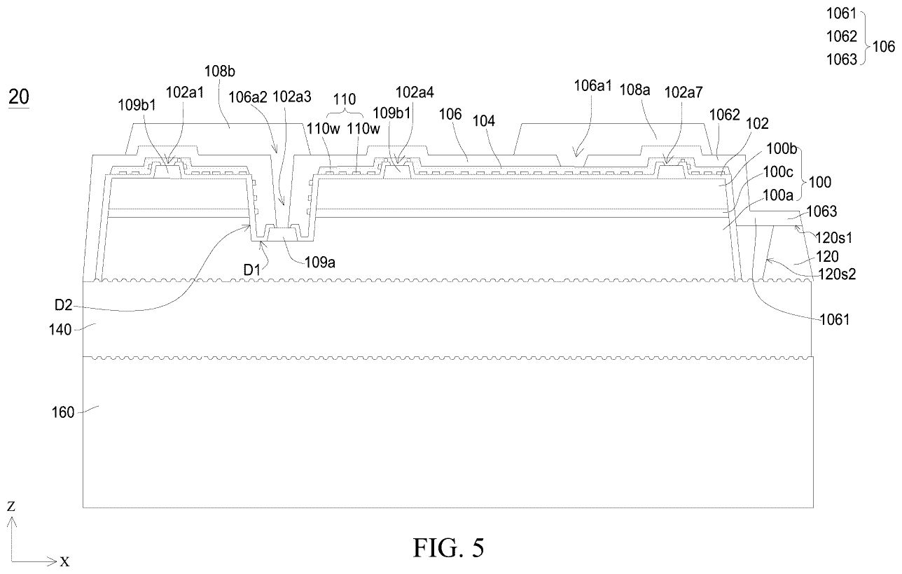

FIG. 5 shows a schematic sectional view of a semiconductor device 20 along C-C′ line in accordance with another embodiment of the present disclosure. The difference between the semiconductor device 20 and the semiconductor device 10 is that in the semiconductor device 20, the metal layer 104 is not located in the recess D of the semiconductor epitaxial structure 100. As shown in FIG. 5, the metal layer 104 is distributed on the first upper surface 100s2 of the semiconductor epitaxial structure 100 and does not fill in the recess D, so the metal layer 104 does not cover the second upper surface D1 and the second sidewall D2. In an embodiment, a process yield may be improved since the metal layer 104 does not fill in the recess D. For example, it may avoid a metal element in the metal layer 104 from migrating and affecting the active region 100c in the semiconductor epitaxial structure 100, thereby the reliability of the semiconductor device 20 may be further improved. The detailed descriptions of positions, relative relationships and materials of the layers or structures as well as structural variations in this embodiment may be referred to the forward embodiments and are not repeatedly described herein.

Based on the above, in the semiconductor device provided in the present disclosure, by arranging the intermediate structure between the metal layer and the insulating layer, the yield and photoelectric characteristics (such as light extraction efficiency) of the device may be improved. The detailed descriptions of positions, relative relationships and materials of the layers or structures as well as structural variations in this embodiment may be referred to the forward embodiments and are not repeatedly described herein.

FIG. 6 shows a schematic sectional view of a semiconductor component 600 in accordance with an embodiment of the present disclosure. The semiconductor component 600 may include a plurality of semiconductor devices 30, each of which corresponds to a structure formed after removing the support structure 120, the connecting layer 140, the base 160 and a portion of the second insulating layer 106 of the semiconductor device (such as the semiconductor device 10 or the semiconductor device 20) as described in any embodiment of the present disclosure. In this embodiment, the semiconductor component 600 including the plurality of the semiconductor device 30 is described as an example. As shown in FIG. 5, the semiconductor component 600 includes a carrier board 80 and the plurality of semiconductor devices 30 located on the carrier board 80. The plurality of the semiconductor device 30 may be fixed on the carrier board 80 with the first electrode pad 108a and the second electrode pad 108b facing downward. In this embodiment, the light emitted by the semiconductor device 30 is emitted from a side of the first semiconductor structure 100a. In accordance with an embodiment, carrier board 80 may be a single-layer structure or a multi-layer structure. In accordance with an embodiment, the material of the carrier board 80 may include glass, polyester, polyimide (PI), BT (Bismaleimide Triazine) resin, PTFE (Polytetrafluoroethylene) resin, phenol (PF) resin or fiberglass epoxy resin (FR4). The detailed descriptions of positions, relative relationships and materials of the layers or structures as well as structural variations in this embodiment may be referred to the forward embodiments and are not repeatedly described herein.

FIG. 7 shows a schematic top view of a semiconductor component 700 in accordance with an embodiment of the present disclosure. The semiconductor component 700 of the embodiment is, for example, a display. As shown in FIG. 7, the semiconductor component 700 includes a carrier board 80 and a plurality of pixel units 82 on the carrier board 80. The pixel units 82 are arranged in an array along the directions parallel to the x-axis and the y-axis, and are arranged at an interval d in the direction parallel to the x-axis. The number of pixel units 82 can be adjusted based on actual needs. For example, in an embodiment, a display with a resolution of 1920×1080 pixels can be provided by the plurality of pixel units 82 included in the semiconductor component 800. In an embodiment, the interval d is less than 1.4 mm, for example, and the interval d is in a range of 0.2 mm to 1.3 mm, such as 0.75 mm, 0.8 mm, 1 mm or 1.25 mm. As shown in FIG. 7, each pixel unit 82 includes a first semiconductor device 84, a second semiconductor device 86, and a third semiconductor device 88 arranged in a direction parallel to the y-axis. One or more of the first semiconductor device 84, the second semiconductor device 86, and the third semiconductor device 88 is the semiconductor device 30 as shown in FIG. 6. In an embodiment, the first semiconductor device 84, the second semiconductor device 86, and the third semiconductor device 88 are all light-emitting devices and can emit red light, green light, and blue light, respectively. In an embodiment, the arrangement order of the light-emitting devices can also be adjusted based on actual needs. For example, the first semiconductor device 84, the second semiconductor device 86, and the third semiconductor device 88 emit red light, blue light, and green light, respectively. Each pixel unit 82 can be electrically connected to a circuit (not shown) on the surface of the carrier board 80, so that the light-emitting devices therein can receive an external signal and emit light in accordance with the external signal. In an embodiment, the carrier board 80 can be bent, and for example, can withstand a radius of curvature less than 50 mm, such as 25 mm or 32 mm.

Based on above, according to the embodiment(s) of the present disclosure, the semiconductor device and the semiconductor component may be provided. For example, by arranging the intermediate structure between the metal layer and the insulating layer, the yield and photoelectric characteristics (such as light extraction efficiency) of the device may be improved. Specifically, the semiconductor device and the semiconductor component of the present disclosure may be applied to products in various fields, such as illumination, display, communication or power supply system, for example, may be used in a light fixture, monitor, an automotive instrument panel, a television, computer, traffic sign, or an outdoor display device.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments may be combined or substituted under proper condition and are not limited to specific embodiments described above. A connection relationship between a specific component and another component specifically described in an embodiment may also be applied in another embodiment and is within the scope as claimed in the present disclosure.

What is claimed is:

1. A semiconductor device, comprising:
a semiconductor epitaxial structure comprising an active region and having a first sidewall and a first upper surface;
a first insulating layer covering the first sidewall and the first upper surface of the semiconductor epitaxial structure and having a second upper surface;
a metal layer located on the first insulating layer;
a second insulating layer located on the metal layer;
a first electrode pad and a second electrode pad located on the second insulating layer; and
an intermediate structure located between the first insulating layer and the metal layer;
wherein the second upper surface of the first insulating layer has a portion directly contacts the metal layer.

2. The semiconductor device of claim 1, wherein the first insulating layer has a plurality of first openings, and the second insulating layer has a plurality of second openings.

3. The semiconductor device of claim 2, wherein the number of the plurality of first openings is greater than the number of the plurality of second openings.

4. The semiconductor device of claim 2, wherein the first insulating layer has two or more of the plurality of first openings with different widths.

5. The semiconductor device of claim 2, wherein when the semiconductor epitaxial structure is equally divided into three parts with the same length in a length direction, one to ten of the plurality of first openings is distributed in each part.

6. The semiconductor device of claim 2, wherein the metal layer fills in one of the plurality of first openings.

7. The semiconductor device of claim 6, wherein the second electrode pad fills in another one of the plurality of first openings.

8. The semiconductor device of claim 2, wherein the first electrode pad fills in one of the plurality of second openings and is in direct contact with the metal layer.

9. The semiconductor device of claim 1, wherein the semiconductor epitaxial structure has a recess, and the semiconductor device further comprises a first contact structure which is located in the recess and is in direct contact with the semiconductor epitaxial structure.

10. The semiconductor device of claim 9, wherein the metal layer is devoid of contacting the first contact structure.

11. The semiconductor device of claim 8, further comprises a second contact structure which is located on the semiconductor epitaxial structure and comprises a plurality of portions separated from each other.

12. The semiconductor device of claim 11, wherein the plurality of portions is in direct contact with the semiconductor epitaxial structure.

13. The semiconductor device of claim 1, wherein the semiconductor epitaxial structure has a recess, and a portion of the metal layer is located in the recess.

14. The semiconductor device of claim 1, wherein the semiconductor epitaxial structure has a recess, and the metal layer is not located in the recess.

15. The semiconductor device of claim 1, wherein the intermediate structure has a thickness greater than 0 Å and less than or equal to 100 Å.

16. The semiconductor device of claim 1, wherein the semiconductor device has a top-view area of 10000 μm² or less.

17. The semiconductor device of claim 1, wherein the first insulating layer comprises a DBR structure.

18. The semiconductor device of claim 1, further comprising a support structure separated from the semiconductor epitaxial structure, wherein the second insulating layer covers the support structure.

19. The semiconductor device of claim 18, wherein the support structure and the semiconductor epitaxial structure comprise the same material.

20. The semiconductor device of claim 1, wherein the intermediate structure comprises a plurality of island-like structures.
